(19) United States
(12) Patent Application Publication
(10) Pub. No.: US 2022/0157609 A1
(43) Pub. Date: May 19, 2022

(54) PRECISE ETCHING APPARATUS FOR PREPARING RECESSED-GATE ENHANCEMENT DEVICE AND ETCHING METHOD FOR THE SAME

(71) Applicant: SOUTH CHINA UNIVERSITY OF TECHNOLOGY, Guangzhou (CN)

(72) Inventors: Guoqiang LI, Guangzhou (CN); Peiye SUN, Guangzhou (CN); Zhikun LIU, Guangzhou (CN); Lijun WAN, Guangzhou (CN); Dingbo CHEN, Guangzhou (CN); Xianfeng QUE, Guangzhou (CN); Shunan YAO, Guangzhou (CN); Runze LI, Guangzhou (CN)

(73) Assignee: SOUTH CHINA UNIVERSITY OF TECHNOLOGY, Guangzhou (CN)

(21) Appl. No.: 17/598,891

(22) PCT Filed: Oct. 27, 2019
(86) PCT No.: PCT/CN2019/113503

§ 371 Date: Sep. 28, 2021

(30) Foreign Application Priority Data
Mar. 29, 2019 (CN) 201910252334.0

(51) Int. Cl. H01L 21/3065; H01J 37/32

(52) U.S. Cl. CPC H01L 21/3065; H01L 29/66462; H01J 37/3211

(57) ABSTRACT

The present invention discloses a precise etching apparatus for preparing a recessed-gate enhancement device and an etching method for the same. The apparatus provided by the present invention includes an inductively-coupled plasma etching chamber, a current detection device, an inductive coil, a radio frequency source, a mechanical pump, and a molecular pump. The current detection device is connected with the inductively-coupled plasma etching chamber. The inductive coil is connected with the inductively-coupled plasma etching chamber. The radio frequency source is connected with the inductive coil. The mechanical pump and the molecular pump are connected with the inductively-coupled plasma etching chamber. When a displayed current value is zero during an HEMT device preparation process, the apparatus shuts off a two-dimensional electron gas channel, and etching is terminated, thereby preventing gate leakage caused by over-etching or damage to the two-dimensional electron gas channel, thus achieving precise etching.

### TECHNICAL FIELD

The present invention relates to the field of dry etching, and in particular to a precise etching apparatus for preparing a recessed-gate enhancement device and an etching method for the same.

### BACKGROUND

With the advantages such as high breakdown voltage, high electron mobility and high saturation rate, GaN HEMT device is regarded as one of the most ideal materials in the next generation of power devices. In recent years, GaN HEMT device has been highly preferred by researchers. Due to stronger spontaneous polarization and piezoelectric polarization effect, most of the conventional HEMT devices are depletion devices. To improve circuit safety and working efficiency while saving the design cost, it is of great significance to achieve an enhancement HEMT device.

In order to achieve the enhancement HEMT device, there are common methods, including a Cascode cascading technology, an F ion implantation technology, a p-type gate structure and a recessed-gate structure.

Cascode cascading technology is a kind of technology used in commercial enhancement HEMT at the earliest. A silica-based enhancement MOSFET is connected with a depletion AlGaN/GaN HEMT device in series, and a gate of the HEMT device is connected with a source electrode of MOSFET such that the HEMT channel keeps normally opening; the on/off of the overall channel is controlled via the gate of the enhancement MOSFET device, thus achieving a high-pressure resistant enhancement HEMT device. But the on/off rate of such an enhancement device mainly depends on a silicon device, which substantially reduces the signal output frequency, limits the exertion of GaN material advantages, and causes a big packaging difficulty. The F ion implantation technology is to introduce F ions in a barrier layer AlGaN under the gate in an ion implantation way, thus promoting the height of the conduction band of the AlGaN layer under the gate; when the conduction band rises to Fermi level above, the two-dimensional electron gas in the channel under the gate is exhausted, thus achieving an enhancement device. But the F ion implantation will cause damage to the device; moreover, poor F stability will cause poorer reliability, instable threshold voltage and other problems to the device. The p-type gate structure is to introduce a layer of p-type doped GaN or AlGaN extension between the artificially doped AlGaN barrier layer and a gate metal, thus rising the conduction band of the whole heterojunction and depleting 2DEG in a channel under gate accordingly, such that the device is transformed into an enhancement mode from a depletion mode. But p-type GaN has a big difficulty in selective growth and activation process; therefore, such kind of chip is extremely expensive. Therefore, the enhancement device prepared by the Cascode cascading technology, F ion implantation technology, and the p-type gate structure hardly achieves the industrialization of the enhancement HEMT device.

At present, a recessed-gate structure is a comparatively promising process technology to achieve the enhancement HEMT device. The recessed-gate structure is a kind of AlGaN barrier layer having a certain thickness in a region below an etching gate to make the threshold voltage of the device shifting forward, and decrease the space between the gate and the two-dimensional electron gas channel layer and improve the control ability of the gate, thereby effectively reducing the short-channel effect of the device and improving the device transconductance and possessing excellent high-frequency characteristics. Therefore, the recessed-gate structure is also a research hotspot of the enhancement AlGaN/GaN HEMT device structure at present.

The preparation of an enhancement device with a recessed-gate structure needs to etch a barrier layer having a certain depth. Due to stable chemical properties of AlGaN, it is difficult to etch the barrier layer by wet etching, and usually, dry etching is used. But in dry etching, it is difficult to control the etching depth; different etching depth has larger influences on device characteristics. Therefore, it needs to master the etching depth precisely. Meanwhile, the plasma produced in etching process has a higher etching rate; unreasonable process control, or a minor change in gas flow, temperature, gas backflow and other state in a reaction chamber will lead to excessive etching, thereby damaging the next layer of material, influencing device stability, and even causing device failure. Therefore, it is of positive significance to design a device capable of achieving precise etching and an etching method thereof for the realization of industrialization of the recessed-gate enhancement HEMT device.

To accurately control the etching depth, an optical emission spectrometry and a laser interferometry are generally used in the industry. The optical emission spectrometry is to judge by means of the intensity of the wavelength light emitted by a plasma reactant or a product; the light intensity of the reactant strengthens and the light intensity of the product weakens at the endpoint of etching. When the etching rate is very slow or etching area is very small, the received light intensity signal is very weak; therefore, the method fails to achieve accurate detection. The laser interferometry is to monitor the etching depth by detecting the change of a film thickness with a laser light source. But the method requires that a sample to be etched has good transmission of light, the laser light must focus on the etched region, and the temperature of the region where the laser light focuses on will increase, thus influencing the etching rate.

The above etching methods have their limitations and thus may not effectively and simply achieve precise etching, and further need to be equipped with a dedicated optical endpoint detector or a laser facility, which increases the control difficulty and increases cost.

### SUMMARY

### Technical Problem

To overcome the shortcomings existing in the prior art, the objective of the present invention is to provide a precise etching apparatus for preparing a recessed-gate enhancement device and an etching method for the same.

Currently, there are shortcomings of difficulties in controlling the etching depth and causing damage to the device in the existing dry etching process. A precise etching apparatus for preparing a recessed-gate enhancement device and an etching method for the same provided by the present invention may overcome the shortcomings in the prior art.

### Solution to the Problems

### Technical Solution

To achieve the above objective, a technical solution provided by the present invention is to guide plate-penetrating electrodes to be communicated with an external current detection device in a plasma etching chamber; and the electrodes are connected with source and drain electrodes of a GaN HEMT device to form a current loop. An etching depth is real-timely monitored by observing a current variation. During an etching process of the recessed-gate, a barrier layer thins constantly, and a concentration of the two-dimensional electron gas decreases, and a current value decreases, when a current value is zero, an enhancement type is achieved, and the etching is terminated, thereby effectively preventing a gate leakage caused by over-etching or damage to the two-dimensional electron gas channel, and achieving a precise etching.

The objective of the present invention is achieved by one of the following technical solutions.

A precise etching apparatus for preparing a recessed-gate enhancement device provided by the present invention includes an inductively-coupled plasma etching chamber, a current detection device, an inductive coil, a radio frequency source, a mechanical pump, and a molecular pump. The current detection device is connected with the inductively-coupled plasma etching chamber via a wire. The inductive coil is connected with the inductively-coupled plasma etching chamber. The radio frequency source is connected with the inductive coil. The mechanical pump and the molecular pump are connected with a side of the inductively-coupled plasma.

Further, the inductively-coupled plasma etching chamber includes a chamber body, a base, a radio frequency bias power source, a plate-penetrating electrode, a probe, a ceramic bushing and a gas valve.

Further, two plate-penetrating electrodes are disposed on a side wall of the chamber body of the inductively-coupled plasma etching chamber. The electrodes are connected with probes and connected with source and drain electrodes of the HEMT device in the chamber body. The electrodes are connected with the current detection device to form a current loop outside the chamber body.

Further, the base is disposed at the bottom (inside) of the inductively-coupled plasma etching chamber; the radio frequency bias power source is connected with a lower portion of the base; and the radio frequency bias power source may increase the bombarding energy of a plasma.

Further, a base bearing a substrate to be etched is disposed in the inner chamber body of the inductively-coupled plasma etching chamber; a radio frequency bias power source is connected with a lower portion of the base, thus increasing the bombarding energy of the plasma.

Further, plate-penetrating electrodes (two) are disposed on the side wall of the chamber body of the inductively-coupled plasma etching chamber; one end of each plate-penetrating electrode is connected with a probe, and another end of each plate-penetrating electrode is connected with the current detection device.

Further, the probe is connected with source and drain electrodes of the HEMT device; the ceramic bushing is disposed on an upper portion of the chamber body of the inductively-coupled plasma etching chamber; the ceramic bushing is communicated with the chamber body of the inductively-coupled plasma etching chamber; the ceramic bushing is connected with the inductive coil; the ceramic bushing communicated with the inductively-coupled plasma etching chamber is disposed on the upper portion of the chamber body of the inductively-coupled plasma etching chamber, an inductively-coupled coil is wound outside the bushing and the inductively-coupled coil is connected with the radio frequency source; a radio frequency current is applied in the inductively-coupled coil to produce an alternating magnetic field, such that a process gas is energized into a high-density plasma.

Further, a top portion of the ceramic bushing is provided with the gas valve, and is communicated with a process gas pipeline via the gas valve.

Further, two valves which are respectively connected to the mechanical pump and the molecular pump are disposed at the bottom of the chamber body of the inductively-coupled plasma etching chamber, such that the mechanical pump and the molecular pump may vacuumize the inner chamber body of the inductively-coupled plasma etching chamber and pump out a reaction gas in etching process timely.

Further, two plate-penetrating electrodes are disposed on the side wall of the chamber body of the inductively-coupled plasma etching chamber; in the chamber body of the inductively-coupled plasma etching chamber, the two plate-penetrating electrodes are connected with source and drain electrodes on the substrate to be etched (HEMT device) by connecting with probes; the two plate-penetrating electrodes are connected with the current detection device to form a closed loop outside the chamber body of the inductively-coupled plasma etching chamber.

Further, the inductive coil is an inductively-coupled coil and wound on the ceramic bushing, a radio frequency current is applied to the inductive coil to produce an alternating magnetic field, such that a process gas is energized into the high-density plasma.

Further, the chamber body of the inductively-coupled plasma etching chamber is made of a high-pressure resistant alloy steel.

Further, the probe is a beryllium copper gold-plated probe.

An etching method for preparing the recessed-gate enhancement HEMT device by using the above precise etching apparatus provided by the present invention includes the following steps.

(1) Sending the substrate to be etched into the chamber body of the inductively-coupled plasma etching chamber, where the substrate to be etched is put on the base;

(2) Respectively connecting the probes and the current detection device with the plate-penetrating electrodes;

(3) Respectively connecting the probes to source and drain electrodes of the same unit on the device, thus forming the current loop;

(4) Opening the valve connected with the mechanical pump and the molecular pump; vacuumizing the inner chamber body of the inductively-coupled plasma etching chamber using the mechanical pump and the molecular pump, loading the etching gas;

(5) Switching on the radio frequency source and the radio frequency bias power source to etch the substrate;

(6) In etching process, the HEMT device has a constantly thinning barrier layer and the two-dimensional electron gas has a reduced concentration, and an output current also changes accordingly; an etching depth is real-timely monitored by observing current; an enhancement etching depth is achieved when a displayed current value is zero, then etching is terminated.

(7) Switching off the radio frequency source and the radio frequency bias power source and sending out the etched substrate to obtain the recessed-gate enhancement HEMT device.

Further, a relationship between the output current and the etching depth is utilized in the step (6) to guide the electrodes to be communicated with the external current detector in the etching chamber, thus forming the current loop.

### Beneficial Effects of the Invention

### Beneficial Effects

Compared with the prior art, the present invention has the following advantages and beneficial effects.

(1) The present invention skillfully utilizes the relational characteristics between the thickness of a barrier layer in the GaN HMET device and the concentration of the two-dimensional electron gas to be skillfully transformed into the relationship between the etching depth and the current value. The etching depth is monitored by directly observing current variation, when a displayed current value is zero, the etching is terminated. The present invention is visual, and has high precision and strong operability.

(2) Most of the existing processes used for controlling the etching depth in dry etching are etching endpoint detection and self-termination etching techniques, featured by complex steps and limited precision. The etching device of the present invention only requires the external connection with a simple current detection device. Therefore, the present invention has a simple structure, a visual result, and no extra addition of processing steps, and is easy to control and beneficial for industrialization.

(3) In etching process, unreasonable process control, or a minor change in gas flow, temperature, gas backflow and other state in a reaction chamber will lead to abnormal etching which may be reflected by abnormal current variation. The device provided by the present invention is beneficial to timely discovery and treatment, thus avoiding product scrap.

### BRIEF DESCRIPTION OF THE DRAWINGS

Description of the Drawings

FIG. 1 shows a structure diagram of a precise etching apparatus for preparing a recessed-gate enhancement device provided by the present invention.

FIG. 2 is a front view showing connection between plate-penetrating electrodes and an inductively-coupled plasma etching chamber in the precise etching apparatus for preparing a recessed-gate enhancement device provided by the present invention.

1: inductively-coupled plasma etching chamber, 2: base, 3: radio frequency bias power source, 4: plate-penetrating electrode, 5: probe, 6: current detection device, 7: ceramic bushing, 8: inductive coil, 9: gas valve, 10: radio frequency source, 11: mechanical pump, and 12: molecular pump.

### EXAMPLES OF THE INVENTION

Detailed Description of the Embodiments

The present invention will be further described in combination with the drawings and examples of the description. But the embodiments and protection scope of the present invention are not limited thereto. It should be pointed that any process not described in detail particularly may be achieved and understood by reference to the prior art by a person skilled in the art.

### EXAMPLE 1

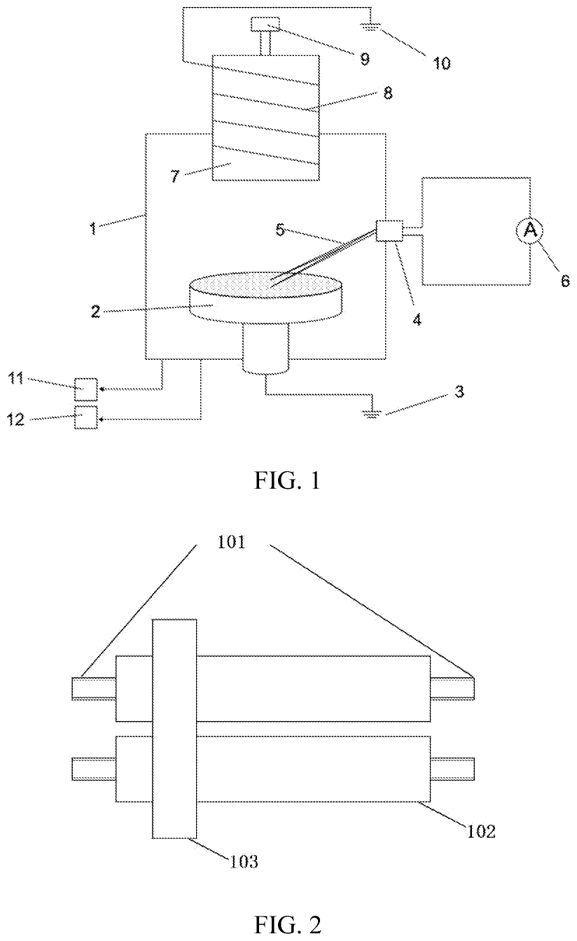

The structure diagram of the precise etching apparatus of the present invention is shown in FIG. 1, and includes an inductively-coupled plasma etching chamber 1, a current detection device 6, an inductive coil 8, a radio frequency source 10, a mechanical pump 11 and a molecular pump 12.

A base 2 is disposed in a central position at the bottom of the chamber body of the inductively-coupled plasma etching chamber 1, used for putting a substrate to be etched. The base 2 is connected with the radio frequency bias power source 3. The radio frequency bias power source 3 provides the bombarding energy of a plasma.

Two plate-penetrating electrodes 4 are disposed in a central position on a side wall of the chamber body of the inductively-coupled plasma etching chamber 1; the inner structure of the plate-penetrating electrodes and the inner structure is connected with the inductively-coupled plasma etching chamber, as shown in FIG. 2. Each plate-penetrating electrode includes a thick lead-out tube 101, a fine lead-out tube 102 and a lead, where the thick lead-out tube is connected with a side wall 103 of the chamber body of the inductively-coupled plasma etching chamber, and is in threaded connection with the fine lead-out tube; the fine wire hole contains a continuous wire lead. In the chamber body of the inductively-coupled plasma etching chamber 1, two plate-penetrating electrodes 4 are respectively connected with two probes 5, and the two probes 5 are respectively connected with source and drain electrodes of the same unit on the substrate to be etched; two plate-penetrating electrodes 4 are connected with the current detection device 6 to form a circuit loop outside the chamber body of the inductively-coupled plasma etching chamber 1.

A ceramic bushing 7 is disposed on an upper portion of the chamber body of the inductively-coupled plasma etching chamber 1; an inductive coil 8 is wound outside the ceramic bushing 7, and the top portion thereof is provided with a gas valve 9; the inductive coil 8 is connected with the radio frequency source 10 to form an inductance alternating magnetic field, such that a process gas from the gas valve 9 is energized into a plasma.

Valves which are respectively connected to the mechanical pump 11 and the molecular pump 12 are disposed at the bottom of the chamber body of the inductively-coupled plasma etching chamber 1, such that the mechanical pump 11 and the molecular pump 12 may vacuumize the chamber body 1 of the inductively-coupled plasma etching chamber and pump out a reaction gas in etching process timely.

### EXAMPLE 2

Example 2 is set as an example to describe the etching method of the present invention; an etching method for preparing a recessed-gate enhancement HEMT device by using the above precise etching apparatus includes the following steps.

(1) A substrate to be etched was sent into the chamber body of the inductively-coupled plasma etching chamber 1, where the substrate to be etched was put on the base 2;

(2) The current detection device 6 was connected with two plate-penetrating electrodes 4;

(3) Two probes 5 were respectively connected with the two plate-penetrating electrodes 4, and were adjusted such that the probes 5 were respectively connected with source and drain electrodes of the same unit on the substrate device to be etched, thus forming a closed loop;

(4) The mechanical pump 11 was switched on to vacuumize the chamber body of the inductively-coupled plasma etching chamber 1;

(5) When the vacuum degree was pumped to 150 m Torr, the molecular pump 12 was switched on to further vacuumize till the chamber body had an internal pressure of 5 mT;

(6) A mixed gas of Cl₂ and BCl₃ was loaded via the gas valve 9;

(7) The radio frequency source 10 was switched on, and a power parameter was set as 250 W; a radio frequency current was applied to the inductive coil 8 connected with the radio frequency source, such that an alternating magnetic field was produced within the ceramic bushing 7 wound by the inductive coil, and then the mixed gas of Cl₂ and BCl₃ was energized into a plasma.

(8) The radio frequency bias power source 3 was switched on, and a power parameter was set as 30 W to increase the ion bombarding energy;

(9) In the etching process, the current variation was observed by the current detection device 6; when a displayed current value was zero, the etching was terminated; then the radio frequency source 10 and the radio frequency bias power source 3 were switched off;

(10) At the end of the etching, the etched substrate was sent out to obtain the recessed-gate enhancement HEMT device.

This example skillfully utilizes the relational characteristics between the thickness of a barrier layer in the GaN HMET device and the concentration of the two-dimensional electron gas to be skillfully transformed into the relationship between the etching depth and the current value. The etching depth is monitored by directly observing the current variation, when a displayed current value is zero, the etching is terminated. The present invention is visual, and has high precision and strong operability.

What is described above are merely detailed embodiments in the present application. It should be indicated that a person skilled in the art may make various corresponding changes and transformations according to the above technical solution described above and concept within the principle of the present application. Moreover, all of these changes and transformations should fall within the protection scope of the claims of the present invention.

1. A precise etching apparatus for preparing a recessed-gate enhancement device, comprising: an inductively-coupled plasma etching chamber, a current detection device, an inductive coil, a radio frequency source, a mechanical pump, and a molecular pump, wherein the current detection device is connected with the inductively-coupled plasma etching chamber via a wire, the inductive coil is connected with the inductively-coupled plasma etching chamber, the radio frequency source is connected with the inductive coil, and the mechanical pump and the molecular pump are connected with the inductively-coupled plasma etching chamber.

2. The precise etching apparatus for preparing a recessed-gate enhancement device according to claim 1, wherein the inductively-coupled plasma etching chamber comprises a chamber body, a base, a radio frequency bias power source, a plate-penetrating electrode, a probe, a ceramic bushing and a gas valve.

3. The precise etching apparatus for preparing a recessed-gate enhancement device according to claim 2, wherein the base is disposed at a bottom of the chamber body of the inductively-coupled plasma etching chamber; a lower portion of the base is connected with the radio frequency bias power source; the radio frequency bias power source increases bombarding energy of a plasma;
the plate-penetrating electrode is disposed on a side wall of the chamber body of the inductively-coupled plasma etching chamber; one end of the plate-penetrating electrode is connected with the probe, and another end of the plate-penetrating electrode is connected to the current detection device.

4. The precise etching apparatus for preparing a recessed-gate enhancement device according to claim 2, wherein the probe is connected with source and drain electrodes on a substrate to be etched; the ceramic bushing is disposed on an upper portion of the chamber body of the inductively-coupled plasma etching chamber and is connected to the inductive coil; a top portion of the ceramic bushing is provided with the gas valve, and is communicated with a process gas pipeline via the gas valve.

5. The precise etching apparatus for preparing a recessed-gate enhancement device according to claim 2, wherein two valves which are respectively connected with the mechanical pump and the molecular pump are disposed at the bottom of the chamber body of the inductively-coupled plasma etching chamber; the mechanical pump and the molecular pump vacuumize the inner chamber body of the inductively-coupled plasma etching chamber via the valves and pump out a reaction gas in etching process.

6. The precise etching apparatus for preparing a recessed-gate enhancement device according to claim 1, wherein two plate-penetrating electrodes are disposed on the side wall of the chamber body of the inductively-coupled plasma etching chamber; in the chamber body of the inductively-coupled plasma etching chamber, the two plate-penetrating electrodes are respectively connected to two probes, and the two probes are connected with source and drain electrodes of a same unit on the substrate to be etched; the two plate-penetrating electrodes are connected with the current detection device to form a closed loop outside the chamber body of the inductively-coupled plasma etching chamber.

7. The precise etching apparatus for preparing a recessed-gate enhancement device according to claim 1, wherein the inductive coil is an inductively-coupled coil and wound on the ceramic bushing, a radio frequency current is applied to the inductive coil to produce an alternating magnetic field, such that a process gas is energized into a high-density plasma.

8. The precise etching apparatus for preparing a recessed-gate enhancement device according to claim 1, wherein the chamber body of the inductively-coupled plasma etching chamber is made of a high-pressure resistant alloy steel.

9. The precise etching apparatus for preparing a recessed-gate enhancement device according to claim 1, wherein the probe is a beryllium copper gold-plated probe.

10. An etching method for preparing a recessed-gate enhancement high electron mobility transistor (HEMT) device by using the precise etching apparatus according to claim 1, comprising the following steps:
(1) sending the substrate to be etched into the chamber body of the inductively-coupled plasma etching chamber, wherein the substrate to be etched is put on the base;
(2) respectively connecting the probes and the current detection device with the plate-penetrating electrodes;
(3) respectively connecting the probes with source and drain electrodes of the same unit on the substrate to be etched, thus forming the closed loop circuit;
(4) opening the valve connected with the mechanical pump and the molecular pump;
vacuumizing the inner chamber body of the inductively-coupled plasma etching chamber with the mechanical pump and the molecular pump, and loading the etching gas;
(5) switching on the radio frequency source and the radio frequency bias power
(6) wherein, in etching process, the HEMT device has a constantly thinning barrier layer and the two-dimensional electron gas has a reduced concentration, and an output current also changes accordingly; an etching depth is real-timely monitored by observing current; an enhancement etching depth is achieved when a displayed current value is zero, then etching is terminated;
(7) switching off the radio frequency source and the bias power source and sending out the etched substrate to obtain the recessed-gate enhancement HEMT device.

11. An etching method for preparing a recessed-gate enhancement high electron mobility transistor (HEMT) device by using the precise etching apparatus according to claim 2, comprising the following steps:
(1) sending the substrate to be etched into the chamber body of the inductively-coupled plasma etching chamber, wherein the substrate to be etched is put on the base;
(2) respectively connecting the probes and the current detection device with the plate-penetrating electrodes;
(3) respectively connecting the probes with source and drain electrodes of the same unit on the substrate to be etched, thus forming the closed loop circuit;
(4) opening the valve connected with the mechanical pump and the molecular pump;
vacuumizing the inner chamber body of the inductively-coupled plasma etching chamber with the mechanical pump and the molecular pump, and loading the etching gas;
(5) switching on the radio frequency source and the radio frequency bias power source to etch the substrate;
(6) wherein, in etching process, the HEMT device has a constantly thinning barrier layer and the two-dimensional electron gas has a reduced concentration, and an output current also changes accordingly; an etching depth is real-timely monitored by observing current; an enhancement etching depth is achieved when a displayed current value is zero, then etching is terminated;
(7) switching off the radio frequency source and the bias power source and sending out the etched substrate to obtain the recessed-gate enhancement HEMT device.

12. An etching method for preparing a recessed-gate enhancement high electron mobility transistor (HEMT) device by using the precise etching apparatus according to claim 3, comprising the following steps:
(1) sending the substrate to be etched into the chamber body of the inductively-coupled plasma etching chamber, wherein the substrate to be etched is put on the base;
(2) respectively connecting the probes and the current detection device with the plate-penetrating electrodes;
(3) respectively connecting the probes with source and drain electrodes of the same unit on the substrate to be etched, thus forming the closed loop circuit;
(4) opening the valve connected with the mechanical pump and the molecular pump; vacuumizing the inner chamber body of the inductively-coupled plasma etching chamber with the mechanical pump and the molecular pump, and loading the etching gas;
(5) switching on the radio frequency source and the radio frequency bias power source to etch the substrate;
(6) wherein, in etching process, the HEMT device has a constantly thinning barrier layer and the two-dimensional electron gas has a reduced concentration, and an output current also changes accordingly; an etching depth is real-timely monitored by observing current; an enhancement etching depth is achieved when a displayed current value is zero, then etching is terminated;
(7) switching off the radio frequency source and the bias power source and sending out the etched substrate to obtain the recessed-gate enhancement HEMT device.

13. An etching method for preparing a recessed-gate enhancement high electron mobility transistor (HEMT) device by using the precise etching apparatus according to claim 4, comprising the following steps:
(1) sending the substrate to be etched into the chamber body of the inductively-coupled plasma etching chamber, wherein the substrate to be etched is put on the base;
(2) respectively connecting the probes and the current detection device with the plate-penetrating electrodes;
(3) respectively connecting the probes with source and drain electrodes of the same unit on the substrate to be etched, thus forming the closed loop circuit;
(4) opening the valve connected with the mechanical pump and the molecular pump; vacuumizing the inner chamber body of the inductively-coupled plasma etching chamber with the mechanical pump and the molecular pump, and loading the etching gas;
(5) switching on the radio frequency source and the radio frequency bias power source to etch the substrate;
(6) wherein, in etching process, the HEMT device has a constantly thinning barrier layer and the two-dimensional electron gas has a reduced concentration, and an output current also changes accordingly; an etching depth is real-timely monitored by observing current; an enhancement etching depth is achieved when a displayed current value is zero, then etching is terminated;
(7) switching off the radio frequency source and the bias power source and sending out the etched substrate to obtain the recessed-gate enhancement HEMT device.

14. An etching method for preparing a recessed-gate enhancement high electron mobility transistor (HEMT) device by using the precise etching apparatus according to claim 5, comprising the following steps:
(1) sending the substrate to be etched into the chamber body of the inductively-coupled plasma etching chamber, wherein the substrate to be etched is put on the base;
(2) respectively connecting the probes and the current detection device with the plate-penetrating electrodes;
(3) respectively connecting the probes with source and drain electrodes of the same unit on the substrate to be etched, thus forming the closed loop circuit;
(4) opening the valve connected with the mechanical pump and the molecular pump; vacuumizing the inner chamber body of the inductively-coupled plasma etching chamber with the mechanical pump and the molecular pump, and loading the etching gas;
(5) switching on the radio frequency source and the radio frequency bias power source to etch the substrate;
(6) wherein, in etching process, the HEMT device has a constantly thinning barrier layer and the two-dimensional electron gas has a reduced concentration, and an output current also changes accordingly; an etching depth is real-timely monitored by observing current; an enhancement etching depth is achieved when a displayed current value is zero, then etching is terminated;
(7) switching off the radio frequency source and the bias power source and sending out the etched substrate to obtain the recessed-gate enhancement HEMT device.

15. An etching method for preparing a recessed-gate enhancement high electron mobility transistor (HEMT) device by using the precise etching apparatus according to claim 6, comprising the following steps:
(1) sending the substrate to be etched into the chamber body of the inductively-coupled plasma etching chamber, wherein the substrate to be etched is put on the base;
(2) respectively connecting the probes and the current detection device with the plate-penetrating electrodes;
(3) respectively connecting the probes with source and drain electrodes of the same unit on the substrate to be etched, thus forming the closed loop circuit;
(4) opening the valve connected with the mechanical pump and the molecular pump;
vacuumizing the inner chamber body of the inductively-coupled plasma etching chamber with the mechanical pump and the molecular pump, and loading the etching gas;
(5) switching on the radio frequency source and the radio frequency bias power source to etch the substrate;
(6) wherein, in etching process, the HEMT device has a constantly thinning barrier layer and the two-dimensional electron gas has a reduced concentration, and an output current also changes accordingly; an etching depth is real-timely monitored by observing current; an enhancement etching depth is achieved when a displayed current value is zero, then etching is terminated;
(7) switching off the radio frequency source and the bias power source and sending out the etched substrate to obtain the recessed-gate enhancement HEMT device.

16. An etching method for preparing a recessed-gate enhancement high electron mobility transistor (HEMT) device by using the precise etching apparatus according to claim 7, comprising the following steps:
(1) sending the substrate to be etched into the chamber body of the inductively-coupled plasma etching chamber, wherein the substrate to be etched is put on the base;
(2) respectively connecting the probes and the current detection device with the plate-penetrating electrodes;
(3) respectively connecting the probes with source and drain electrodes of the same unit on the substrate to be etched, thus forming the closed loop circuit;
(4) opening the valve connected with the mechanical pump and the molecular pump; vacuumizing the inner chamber body of the inductively-coupled plasma etching chamber with the mechanical pump and the molecular pump, and loading the etching gas;
(5) switching on the radio frequency source and the radio frequency bias power source to etch the substrate;
(6) wherein, in etching process, the HEMT device has a constantly thinning barrier layer and the two-dimensional electron gas has a reduced concentration, and an output current also changes accordingly; an etching depth is real-timely monitored by observing current; an enhancement etching depth is achieved when a displayed current value is zero, then etching is terminated;
(7) switching off the radio frequency source and the bias power source and sending out the etched substrate to obtain the recessed-gate enhancement HEMT device.

17. An etching method for preparing a recessed-gate enhancement high electron mobility transistor (HEMT) device by using the precise etching apparatus according to claim 8, comprising the following steps:
(1) sending the substrate to be etched into the chamber body of the inductively-coupled plasma etching chamber, wherein the substrate to be etched is put on the base;
(2) respectively connecting the probes and the current detection device with the plate-penetrating electrodes;
(3) respectively connecting the probes with source and drain electrodes of the same unit on the substrate to be etched, thus forming the closed loop circuit;
(4) opening the valve connected with the mechanical pump and the molecular pump; vacuumizing the inner chamber body of the inductively-coupled plasma etching chamber with the mechanical pump and the molecular pump, and loading the etching gas;
(5) switching on the radio frequency source and the radio frequency bias power source to etch the substrate;
(6) wherein, in etching process, the HEMT device has a constantly thinning barrier layer and the two-dimensional electron gas has a reduced concentration, and an output current also changes accordingly; an etching depth is real-timely monitored by observing current; an enhancement etching depth is achieved when a displayed current value is zero, then etching is terminated;
(7) switching off the radio frequency source and the bias power source and sending out the etched substrate to obtain the recessed-gate enhancement HEMT device.

18. An etching method for preparing a recessed-gate enhancement high electron mobility transistor (HEMT) device by using the precise etching apparatus according to claim 9, comprising the following steps:
(1) sending the substrate to be etched into the chamber body of the inductively-coupled plasma etching chamber, wherein the substrate to be etched is put on the base;
(2) respectively connecting the probes and the current detection device with the plate-penetrating electrodes;
(3) respectively connecting the probes with source and drain electrodes of the same unit on the substrate to be etched, thus forming the closed loop circuit;
(4) opening the valve connected with the mechanical pump and the molecular pump; vacuumizing the inner chamber body of the inductively-coupled plasma etching chamber with the mechanical pump and the molecular pump, and loading the etching gas;
(5) switching on the radio frequency source and the radio frequency bias power source to etch the substrate;
(6) wherein, in etching process, the HEMT device has a constantly thinning barrier layer and the two-dimensional electron gas has a reduced concentration, and an output current also changes accordingly; an etching depth is real-timely monitored by observing current; an enhancement etching depth is achieved when a displayed current value is zero, then etching is terminated;
(7) switching off the radio frequency source and the bias power source and sending out the etched substrate to obtain the recessed-gate enhancement HEMT device.
